(19) United States
(12) Patent Application Publication
(10) Pub. No.: US 2022/0172934 A1
(43) Pub. Date: Jun. 2, 2022

(54) METHOD OF DIAGNOSING CHAMBER CONDITION AND SUBSTRATE PROCESSING APPARATUS

(71) Applicant: TOKYO ELECTRON LIMITED, Tokyo (JP)

(72) Inventors: Yoshihiro HASHIMOTO, Miyagi (JP); Ryuji OHTANI, Miyagi (JP)

(21) Appl. No.: 17/536,881

(22) Filed: Nov. 29, 2021

(30) Foreign Application Priority Data
Nov. 30, 2020 (JP) 2020-197999

(51) Int. Cl. H01J 37/32

(52) U.S. Cl. CPC H01J 37/32972; H01J 37/3222; H01J 37/32495; H01J 37/32862

(57) ABSTRACT

A method of diagnosing a condition of a chamber in a substrate processing apparatus, includes cleaning an interior of the chamber; generating a plasma from a gas containing a helium gas in the chamber; measuring an emission intensity of fluorine in the interior of the chamber; and diagnosing the condition of the chamber based on the emission intensity.

### CROSS-REFERENCE TO RELATED APPLICATION

This application is based upon and claims the benefit of priority from Japanese Patent Application No. 2020-197999, filed on Nov. 30, 2020, the entire contents of which are incorporated herein by reference.

### TECHNICAL FIELD

The present disclosure relates to a method of diagnosing a chamber condition and a substrate processing apparatus.

### BACKGROUND

For example, Patent Document 1 discloses a method of returning a substrate processing apparatus, which is capable of determining an abnormality of the substrate processing apparatus without lowering the operation rate of the substrate processing apparatus.

### PRIOR ART DOCUMENT

### Patent Document

Patent Document 1: Japanese laid-open publication No. 2006-140237

### SUMMARY

According to one embodiment of the present disclosure, there is provided a method of diagnosing a condition of a chamber in a substrate processing apparatus, including: cleaning an interior of the chamber; generating a plasma from a gas containing a helium gas in the chamber; measuring an emission intensity of fluorine in the interior of the chamber; and diagnosing the condition of the chamber based on the emission intensity.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view showing the schematic configuration of a substrate processing apparatus in which a method of diagnosing a chamber condition according to an embodiment of the present disclosure is used.

FIG. 2 is a flow chart of the method of diagnosing the chamber condition according to the present embodiment.

FIG. 3 is a flow chart of the method of diagnosing the chamber condition according to the present embodiment.

FIG. 4 is a flow chart of the method of diagnosing the chamber condition according to the present embodiment.

FIG. 5 is a conceptual diagram for a time axis of apparatus diagnosis using the method of diagnosing the chamber condition according to the present embodiment.

FIG. 6 is a diagram showing time-series data of emission intensity in which the method of diagnosing the chamber condition according to the present embodiment is used.

FIG. 7 is a diagram showing time-series data of the in-plane average of polysilicon etching rates in which the method of diagnosing the chamber condition according to the present embodiment is used.

FIG. 8 is a diagram showing the correlation between the in-plane average of polysilicon etching rates and the emission intensity in which the method of diagnosing the chamber condition according to the present embodiment is used.

FIG. 9 is a diagram showing the relationship between generated plasma and the emission intensity of a predetermined wavelength.

FIG. 10 is a diagram showing the relationship between generated plasma and the emission intensity of a predetermined wavelength.

FIG. 11 is a diagram showing time-series data of emission intensity in which the method of diagnosing the chamber condition according to the present embodiment is used.

FIG. 12 is a diagram showing the correlation between the in-plane average of polysilicon etching rates and the emission intensity in which the method of diagnosing the chamber condition according to the present embodiment is used.

### DETAILED DESCRIPTION

Hereinafter, embodiments for carrying out the present disclosure will be described with reference to the drawings. Throughout the present disclosure and the drawings, substantially the same configurations are denoted by the same reference numerals, and therefore, explanation thereof will not be repeated. For the sake of ease of understanding, the scale of each part in the drawing may differ from the actual scale. Regarding terms such as “parallel”, “right angle”, “orthogonal”, “horizontal”, “vertical”, “top and bottom”, “left and right” and the like, such a deviation as not to impair the effects of the embodiments is allowed. The shape of a corner portion is not limited to a right angle, but may be rounded in a bow shape. The terms such as “parallel”, “right angle”, “orthogonal”, “horizontal”, “vertical” may include substantially parallel, substantially right angle, substantially orthogonal, substantially horizontal, and substantially vertical, respectively.

### Overall Configuration of Substrate Processing Apparatus 1

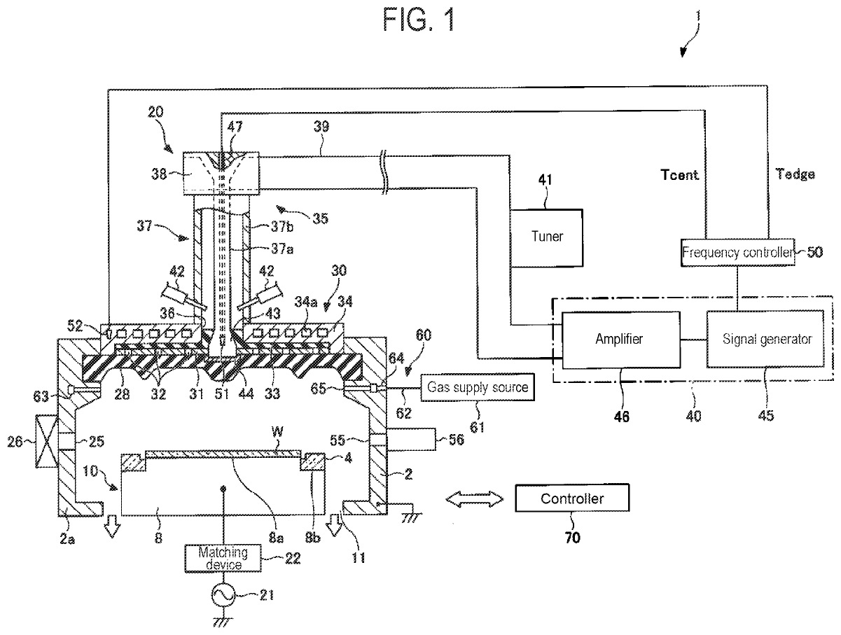

First, an example of the overall configuration of the substrate processing apparatus 1 will be described with reference to FIG. 1. FIG. 1 is a cross-sectional view showing the schematic configuration of the substrate processing apparatus 1 in which a method of diagnosing a chamber condition according to an embodiment of the present disclosure is used. In this embodiment, an example in which the substrate processing apparatus 1 is a microwave plasma processing apparatus using a slot antenna will be described. The microwave plasma processing apparatus of the substrate processing apparatus 1 is, for example, an apparatus that performs plasma etching of polysilicon.

As shown in FIG. 1, the substrate processing apparatus 1 includes a grounded airtight chamber 2. The chamber 2 is made of metal, for example, aluminum or stainless steel.

A ceramics thermal-sprayed film may be formed on the inner surface of the chamber 2. The ceramics thermal-sprayed film may include at least one selected from the group consisting of aluminum oxide, yttrium oxide, yttrium fluoride, and yttrium oxyfluoride. The inner surface of the chamber 2 may be formed of a material containing any one of aluminum oxide, yttrium oxide, yttrium fluoride, and yttrium oxyfluoride.

A stage 10 includes a main body 8 and an annular member (edge ring) 4. The main body 8 has a central region 8a for supporting a substrate W, and an annular region 8b for supporting the annular member 4. The substrate W is disposed on the central region 8a of the main body 8, and the annular member 4 is disposed on the annular region 8b of the main body 8 so as to surround the substrate W on the central region 8a of the main body 8. The main body 8 includes a base and an electrostatic chuck. The base includes a conductive member (lower electrode). The electrostatic chuck is disposed on the base. Further, although not shown, the stage 10 may include a temperature adjusting module configured to adjust at least one of the electrostatic chuck and the substrate W to a target temperature. The temperature adjusting module may include a heater, a flow path, or a combination thereof. A temperature adjusting fluid such as a refrigerant or a heat transfer gas flows through the flow path.

The lower electrode of the main body 8 is electrically connected to a radio frequency power supply 21 via a power feeding rod and a matching unit. The radio frequency power supply 21 supplies a radio frequency bias to the lower electrode. The frequency of the radio frequency bias generated by the radio frequency power supply is a predetermined frequency suitable for controlling the energy of ions drawn into the substrate W, for example, 13.56 MHz. The matching unit accommodates a matching device 22 for matching the impedance on the radio frequency power supply side with the impedance on the load side such as the electrode, plasma, and chamber 2. The matching device 22 contains, for example, a blocking capacitor for self-bias generation.

The stage 10 includes substrate support pins (not shown) for supporting and raising/lowering the substrate W. The substrate support pins are provided so as to move upward and downward with respect to the surface of the stage 10.

The substrate processing apparatus 1 includes an exhaust port 11 that opens at the bottom of the chamber 2. The exhaust port 11 is connected to a TMP (Turbo Molecular Pump) or a DP (Dry Pump) (none of which is shown) via an APC (Automatic Pressure Control) valve (not shown). The TMP and the DP exhaust a gas and the like into the chamber 2, and the APC valve controls the internal pressure of the chamber 2.

The chamber 2 has, on its sidewall, a loading/unloading port 25 for loading/unloading the substrate W in/from a transfer chamber (not shown) adjacent to the substrate processing apparatus 1, and a gate valve 26 for opening/closing the loading/unloading port 25.

The upper part of the chamber 2 has an opening. The substrate processing apparatus 1 includes a microwave plasma source 20 so as to face the opening.

The microwave plasma source 20 includes an antenna part 30 and a microwave transmitting part 35.

The antenna part 30 includes a microwave-transmitting plate 28, a slot antenna 31, and a slow-wave material 33.

The microwave-transmitting plate 28 is formed of a dielectric material, for example, quartz or ceramics such as aluminum oxide (Al₂O₃). The microwave-transmitting plate 28 is fitted in the upper part of the sidewall of the chamber 2 so as to close the opening of the chamber 2. The substrate processing apparatus 1 includes a seal ring between the chamber 2 and the microwave-transmitting plate 28. The seal ring is provided to keep the interior of the chamber 2 airtight.

The slot antenna 31 has a disc-like shape corresponding to the microwave-transmitting plate 28. The slot antenna 31 is provided so as to be in close contact with the microwave-transmitting plate 28. The slot antenna 31 is locked to the upper end of the sidewall of the chamber 2. The slot antenna 31 is made of a conductive material.

The slot antenna 31 is formed of, for example, a copper plate or aluminum plate whose surface is silver- or gold-plated. The slot antenna 31 includes a plurality of slots 32 for radiating microwaves. The slots 32 are formed so as to penetrate the slot antenna 31 in a predetermined pattern.

The pattern of the slots 32 is appropriately set so that the microwave is radiated evenly. As an example of the pattern, a plurality of pairs of slots 32 may be arranged concentrically with two slots 32 arranged in pairs in a T shape. The length and arrangement interval of the slots 32 are determined according to the effective wavelength (λg) of a microwave. For example, the slots 32 are arranged so that their intervals are λg/4, λg/2, or λg.

The slot 32 may have another shape such as a circular shape or an arc shape. Further, the arrangement form of the slots 32 is not particularly limited, and the slots 32 may be arranged in a spiral shape or a radial shape in addition to the concentric circle shape. The pattern of the slots 32 is appropriately set so as to have the microwave radiation characteristics from which a desired plasma density distribution can be obtained.

The slow-wave material 33 is provided in close contact with the upper surface of the slot antenna 31. The slow-wave material 33 is formed of a dielectric having a dielectric constant larger than that of vacuum, for example, quartz, ceramics (Al₂O₃), a resin such as polytetrafluoroethylene, or polyimide. The slow-wave material 33 has a function of making the wavelength of the microwave shorter than that in vacuum to make the slot antenna 31 smaller.

The thicknesses of the microwave-transmitting plate 28 and the slow-wave material 33 are adjusted so that the equivalent circuit formed by the slow-wave material 33, the slot antenna 31, the microwave-transmitting plate 28, and plasma satisfies the resonance condition. The thickness of the slow-wave material 33 can be adjusted to adjust the phase of the microwave.

The phase of the microwave is adjusted to adjust the thickness of the junction of the slot antenna 31 so that the junction of the slot antenna 31 becomes the “belly” of a standing wave. Further, by adjusting the thickness of the junction of the slot antenna 31 so that the junction of the slot antenna 31 becomes the “belly” of the standing wave, the reflection of the microwave is minimized and the radiant energy of the microwave is maximized. Further, the interfacial reflection of the microwave can be prevented by using the same material for the slow-wave material 33 and the microwave-transmitting plate 28.

Further, the slot antenna 31 and the microwave-transmitting plate 28 may be arranged apart from each other, and the slow-wave material 33 and the slot antenna 31 may be arranged apart from each other.

The antenna part 30 includes a shield lid 34 made of a metal material such as aluminum, stainless steel, or copper so as to cover the slot antenna 31 and the slow-wave material 33. The shield lid 34 includes a cooling water flow path 34a formed inside. By flowing cooling water through the cooling water flow path 34a, the shield lid 34 cools the slow-wave material 33, the slot antenna 31, and the microwave-transmitting plate 28. The shield lid 34 is also grounded.

The microwave transmitting part 35 includes a coaxial waveguide 37, a mode converter 38, a waveguide 39, a microwave oscillator 40, and a tuner 41.

The coaxial waveguide 37 is inserted from above the opening 36 formed in the center of the upper wall of the shield lid 34. The coaxial waveguide 37 includes a hollow rod-shaped inner conductor 37a and a cylindrical outer conductor 37b. The inner conductor 37a and the outer conductor 37b are arranged concentrically. Each of the inner conductor 37a and the outer conductor 37b extends upward from the shield lid 34. The inner conductor 37a is provided with a taper connector 43 at the lower end thereof. The taper connector 43 is connected to the slot antenna 31. The taper connector 43 includes a metal cover 44 at the leading end thereof.

The mode converter 38 is connected to the upper end of the coaxial waveguide 37. The waveguide 39 is connected to the mode converter 38. The shape of the waveguide 39 is rectangular in cross section. One end of the waveguide 39 is connected to the mode converter 38 and the other end thereof is connected to the microwave oscillator 40.

The microwave oscillator 40 includes a signal generator 45 and an amplifier 46. The signal generator 45 outputs a signal having a predetermined frequency to the amplifier 46. The amplifier 46 amplifies a signal waveform from the signal generator 45 and oscillates a microwave of predetermined power. The amplifier 46 also performs frequency modulation. The amplifier 46 can modulate the frequency of the microwave between 2,400 and 2,500 MHz (2.4 to 2.5 GHz), for example, when the center frequency thereof is 2,450 MHz (2.45 GHz). The center frequency of the microwave is not limited to 2,450 MHz, but may be various frequencies such as 8.35 GHz, 1. 98 GHz, 860 MHz, and 915 MHz.

The tuner 41 is provided in the middle of the waveguide 39. The tuner 41 matches the impedance of a load (plasma) in the chamber 2 with the characteristic impedance of a power supply of the microwave oscillator 40.

The microwave oscillated by the microwave oscillator 40 propagates through the waveguide 39 in a TE mode. The mode converter 38 converts the microwave propagation mode from the TE mode to a TEM mode. Then, the mode converter 38 outputs the microwave converted to the TEM mode to the coaxial waveguide 37. The microwave output to the coaxial waveguide 37 is guided to the slot antenna 31.

Even when the mode is converted by the mode converter 38, some TE mode microwaves may remain. Even when the TE mode microwaves remain, the remaining microwaves of TE mode components are converted into the TEM mode while propagating through the coaxial waveguide 37.

The inner conductor 37a of the coaxial waveguide 37 has a hole 47 in the central portion thereof, which extends from the upper portion thereof to the taper connector 43. As a temperature detector, a first thermocouple 51 is inserted into the hole 47 up to the position of the taper connector 43. The temperature of the central portion of the antenna part 30 is detected by the first thermocouple 51. On the other hand, as another temperature detector, a second thermocouple 52 is provided at the end portion of the shield lid 34. The temperature at the end portion of the antenna part 30 is detected by the second thermocouple 52.

A signal of the temperature (Tcent) at the center of the antenna part detected by the first thermocouple 51 and a signal of the temperature (Tedge) at the end portion of the antenna part detected by the second thermocouple 52 are input to a frequency controller 50 that control the frequency of the microwave. Both the first thermocouple 51 and the second thermocouple 52 are inserted from the outside of the antenna part 30 and are arranged in the atmospheric portion.

The frequency controller 50 gives the microwave oscillator 40 a command to optimize a plasma density distribution based on the temperature Tcent detected by the first thermocouple 51 and the temperature Tedge detected by the second thermocouple 52. The microwave oscillator 40 controls the oscillation frequency of the output microwave based on the command from the frequency controller 50.

The temperature Tcent and the temperature Tedge correlate with the temperatures of the central portion and the edge portion of the lower surface of the microwave-transmitting plate 28 in the chamber 2, respectively. Further, the distribution of an electric field radiated from the slot antenna 31 can be manipulated by varying the oscillation frequency of the microwave, so that the plasma density distribution can be controlled with high accuracy.

The microwave plasma source 20 includes a plurality of stub members 42 in the lower portion of the coaxial waveguide 37. The plurality of stub members 42 are provided in the circumferential direction. Each of the stub members 42 can extend from the outer conductor 37b toward the inner conductor 37a. Each stub member 42 can adjust the propagation of microwave in the circumferential direction by adjusting a distance between the leading end thereof and the inner conductor 37a.

The substrate processing apparatus 1 further includes a gas supply part 60 that supplies a gas into the chamber 2 via the sidewall of the chamber 2. The gas supply part 60 includes a gas supply source 61, a pipe 62, a buffer chamber 63, a gas flow path 64, and a gas discharge port 65.

The gas supply source 61 supplies an appropriate gas according to plasma processing. The pipe 62 connects the gas supply source 61 and the chamber 2. The pipe 62 is provided between the gas supply source 61 and the chamber 2. The buffer chamber 63 is provided in an annular shape along the sidewall of the chamber 2. The gas flow path 64 connects the pipe 62 and the buffer chamber 63. A plurality of gas discharge ports 65 are horizontally provided so as to face the chamber 2 at equal intervals from the buffer chamber 63.

The appropriate gas is supplied from the gas supply part 60 according to the plasma processing. Polysilicon etching processing is exemplified as the plasma processing, and a process gas for this exemplary embodiment is a gas such as a chlorine gas (Cl₂ gas), a hydrogen bromide gas (HBr gas), or a nitrogen trifluoride gas (NF₃ gas), or an inert gas such as a helium gas (He gas).

A plurality of gas supply sources 61 are provided according to the number of gases (type of gas). The pipe 62 extends from each of the gas supply sources 61. The pipe 62 is provided with a valve and a flow rate controller such as a mass flow controller (neither shown).

A glass window 55 is provided on the sidewall of the chamber 2. A spectroscope 56 is provided at a position facing the glass window 55. The spectroscope 56 receives light radiated from the plasma inside the chamber 2 through the glass window 55. Then, the spectroscope 56 measures the emission intensity (spectral intensity) of a specific wavelength from the received light.

The substrate processing apparatus 1 includes a controller 70. The controller 70 controls various components of the substrate processing apparatus 1, for example, the microwave oscillator 40, the valve of the gas supply part 60, the spectroscope 56, the flow rate controller, and the like. The controller 70 includes a main controller having a CPU (Central Processing Unit) (computer), an input device (keyboard, mouse, etc.), an output device (printer, etc.), a display device (display, etc.), and a storage device (storage medium).

The storage device stores parameters of various processes executed by the substrate processing apparatus 1. Further, the storage device is configured with a non-transitory computer-readable storage medium in which programs for controlling the processes executed by the substrate processing apparatus 1, that is, process recipes, are stored. The main controller calls a predetermined process recipe stored in the storage medium and controls the substrate processing apparatus 1 to perform a predetermined process based on the process recipe.

In the substrate processing apparatus 1, first, the gate valve 26 is opened and the substrate W to be processed is loaded into the chamber 2 and is placed on the stage 10. Then, in the substrate processing apparatus 1, the process gases (for example, Cl₂ gas, HBr gas, etc.) are introduced into the chamber 2 from the gas supply part 60 at predetermined flow rates and a flow rate ratio, so that the internal pressure of the chamber 2 is set to a predetermined value by the APC valve.

Further, in the substrate processing apparatus 1, the microwave is supplied into the chamber 2 from the microwave oscillator 40. Further, radio frequency power is supplied from the radio frequency power supply 21 to the stage. The process gas discharged from the gas discharge port 65 is turned into plasma, and the substrate W is etched by radicals and ions in the plasma.

### Diagnosis Method of Chamber Condition

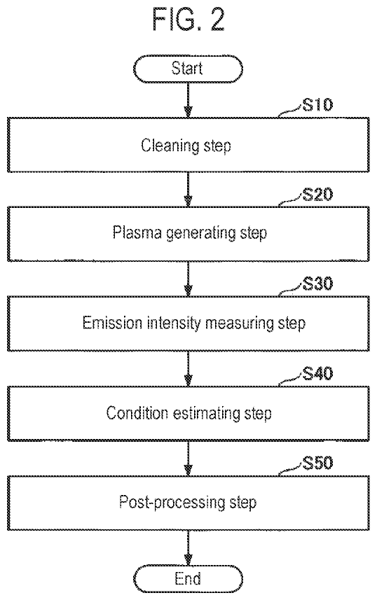

A method of diagnosing the condition of the chamber 2 (chamber condition) of the substrate processing apparatus 1 will be described. FIG. 2 is a flow chart of the method of diagnosing the chamber condition according to the present embodiment.

The method of diagnosing the chamber condition of the present embodiment diagnoses the condition of the chamber by focusing on fluorine derived from the inner surface of the chamber. The fluorine derived from the inner surface of the chamber indicates that fluorine contained in a process gas adheres to a thermal sprayed film forming the inner surface of the chamber, enters the thermal-sprayed film, or is originally contained in the thermal sprayed film itself. The amount of fluorine derived from the inner surface of the chamber affects the chamber condition. Specifically, in the method of diagnosing the chamber condition of the present embodiment, the chamber condition is diagnosed based on the emission intensity (spectral intensity) of fluorine when plasma is generated using a helium gas.

### Step S10

First, the controller 70 performs a cleaning step of cleaning the interior of the chamber 2. In the cleaning step, for example, fluorine and the like adhering to the interior of the chamber 2 when the substrate is processed are removed. By cleaning the interior of the chamber 2, the interior of the chamber is returned to an initial state.

### Step S20

Next, the controller 70 performs a plasma generating step of generating plasma of one or more kinds of inert gases containing a helium gas and no argon gas inside the chamber 2. In other words, a plasma generating step of generating plasma from a gas containing a helium gas or a gas obtained by mixing a helium gas with one or more kinds of inert gases containing no argon gas is performed inside the chamber 2.

In the plasma generating step, for example, a dummy substrate different from a product substrate made of silicon may be placed on the central region 8a of the main body 8. Then, the controller 70 is configured to control the gas supply part 60 to supply one or more kinds of inert gases containing the helium gas and no argon gas into the chamber 2. In a state where one or more kinds of inert gases containing the helium gas and not argon gas are supplied into the chamber 2, the controller 70 is configured to control the microwave oscillator 40 to supply the microwave into the chamber 2 and control the radio frequency power supply 21 to supply the radio frequency power to the stage.

As described above, the plasma of one or more kinds of inert gases containing the helium gas and no argon gas is generated inside the chamber 2. In other words, the plasma of the helium gas or a gas obtained by mixing the helium gas with one or more kinds of inert gases containing no argon gas is generated.

In the method of diagnosing the chamber condition of the present embodiment, one or more kinds of inert gases containing the helium gas and no argon gas are used to generate the plasma. The helium gas is used because, as will be described later, the time from plasma generation to stabilization is short. Further, it is used because a sputter rate of helium is smaller than that of argon and, accordingly, a damage to the chamber is reduced.

Since the emission wavelength of argon often overlaps in many portions with the emission wavelength of fluorine, an inert gas other than argon is used for a mixed gas. Examples of the inert gas may include a xenon gas, a neon gas, a krypton gas, and the like. The one or more kinds of inert gases containing the helium gas and no argon gas may be, for example, a helium gas only, or a mixture of a helium gas and an inert gas such as a xenon gas, a neon gas, a krypton gas, or the like other than an argon gas. That is, the mixture may include at least one selected from the group consisting of a xenon gas, a neon gas and a krypton gas.

### Step S30

Next, the controller 70 performs an emission intensity measuring step of measuring the emission intensity of fluorine inside the chamber. The controller 70 controls the spectroscope 56 to measure the emission intensity of the plasma inside the chamber 2. Specifically, the controller 70 controls the spectroscope 56 to measure the emission intensity of fluorine. For example, the controller 70 controls the spectroscope 56 to measure the emission intensity at 686 nm which is the emission wavelength of fluorine.

### Step S40

Next, the controller 70 diagnoses the condition of the chamber 2 (chamber condition) based on the emission intensity measured in step S30.

For example, when the emission intensity of fluorine measured in step S30 is equal to or higher than a first threshold value and equal to or lower than a second threshold value larger than the first threshold value, the controller 70 determines that the condition of the chamber 2 (chamber condition) is normal (normal condition).

When the emission intensity of fluorine measured in step S30 is lower than the first threshold value, the controller 70 diagnoses that the condition of the chamber 2 (chamber condition) is in a condition in which the inner surface of the chamber 2 is deficient in fluorine (fluorine deficient condition).

Further, when the emission intensity of fluorine measured in step S30 is greater than the second threshold value, the controller 70 diagnoses that the condition of the chamber 2 (chamber condition) is in a condition in which the inner surface of the chamber 2 is in excess of fluorine (fluorine excessive condition).

Furthermore, when the emission intensity of fluorine measured in step S30 is less than a third threshold value smaller than the first threshold value, or when the emission intensity is greater than a fourth threshold value larger than the second threshold value, it is diagnosed that the condition of the chamber 2 (chamber condition) is in a condition in which parts in the chamber 2 are deteriorated and need to be replaced (parts deteriorated condition).

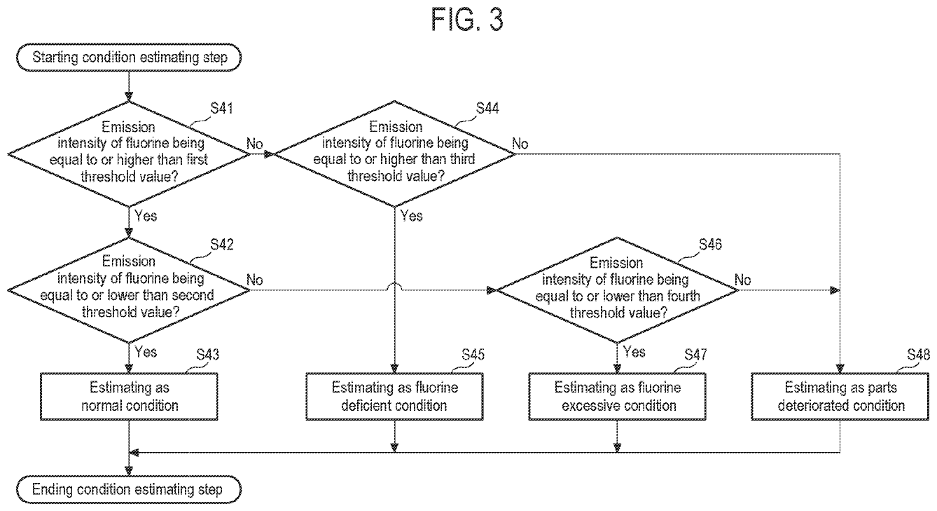

A specific process flow will be described. FIG. 3 is a flow chart of the method of diagnosing the chamber condition according to the present embodiment. Specifically, it is a flow chart of a condition estimating step of step S40.

First, in step S41, the controller 70 determines whether or not the emission intensity of fluorine measured in step S30 is equal to or greater than the first threshold value. When the emission intensity of fluorine measured in step S30 is equal to or greater than the first threshold value (“Yes” in step S41), the controller 70 determines whether or not the emission intensity of fluorine measured in step S30 is equal to or less than the second threshold value larger than the first threshold value (step S42). When the emission intensity of fluorine measured in step S30 is equal to or less than the second threshold value larger than the first threshold value (“Yes” in step S42), the controller 70 estimates that the condition of the chamber 2 (chamber condition) of the substrate processing apparatus 1 is in the normal condition (step S43).

In step S41, when the emission intensity of fluorine measured in step S30 is less than the first threshold value (“No” in step S41), the controller 70 determines whether or not the emission intensity of fluorine measured in step S30 is equal to or greater than the third threshold value smaller than the first threshold value (step S44). When the emission intensity of fluorine measured in step S30 is equal to or greater than the third threshold value (“Yes” in step S44), the controller 70 estimates that the condition of the chamber 2 (chamber condition) of the substrate processing apparatus 1 is the fluorine deficient condition (step S45).

In step S42, when the emission intensity of fluorine measured in step S30 is greater than the second threshold value (“No” in step S42), the controller 70 determines whether or not the emission intensity of fluorine measured in step S30 is equal to or less than the fourth threshold value larger than the second threshold value (step S46). When the emission intensity of fluorine measured in step S30 is equal to or less than the fourth threshold value (“Yes” in step S46), the controller 70 estimates that the condition of the chamber 2 (chamber condition) of the substrate processing apparatus 1 is the fluorine excessive condition (step S47).

In step S44, when the emission intensity of fluorine measured in step S30 is less than the third threshold value (“No” in step S44), the controller 70 estimates that the condition of the chamber 2 (chamber condition) of the substrate processing apparatus 1 is the parts deteriorated condition (step S48). Further, in step S46, when the emission intensity of fluorine measured in step S30 is greater than the fourth threshold value (“No” in step S46), the controller 70 estimates that the condition of the chamber 2 (chamber condition) of the substrate processing apparatus 1 is the parts deteriorated condition (step S48). In the parts deteriorated condition, the controller 70 determines that the normal condition cannot be obtained even when processes of steps S53 and S54 of a post-processing step, which will be described later, are performed, and instructs the parts to be replaced.

Further, for example, as will be described later, by estimating a polysilicon etching rate at the time of etching the substrate W from the emission intensity of fluorine measured in step S30, the controller 70 may estimate whether or not the condition of the chamber 2 is in a condition in which the substrate W can be etched at a desired polysilicon etching rate.

### Step S50

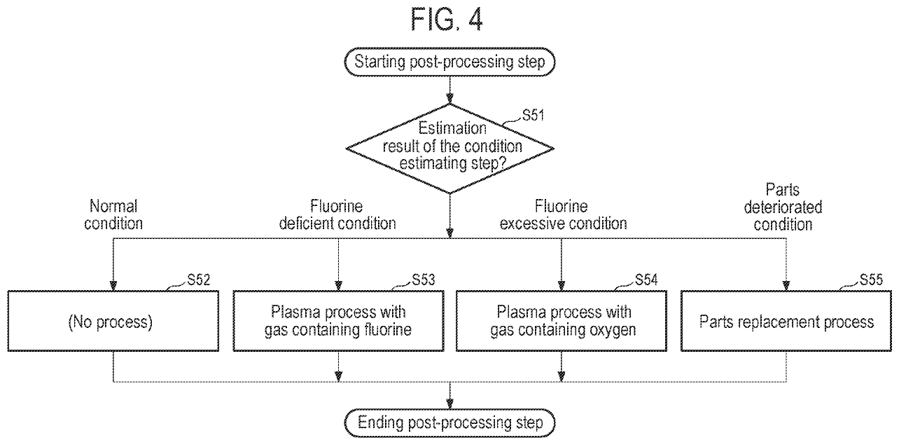

Next, the controller 70 performs a post-processing step based on the diagnosis result in step S40. The details of the process of step S50 will be described. FIG. 4 is a flow chart of the method of diagnosing the chamber condition according to the present embodiment. Specifically, FIG. 4 is a flow chart of the post-processing step of step S50.

In the post-processing step of step S50, in step S51, the controller 70 performs a process based on the estimation result of the condition estimating step of step S40.

In step S51, when it is estimated in the condition estimating step of step S40 that the condition of the chamber 2 is normal (“normal condition” in step S51), the post-processing step is terminated without any particular post-processing step (step S52).

In step S51, when it is estimated in the condition estimating step of step S40 that the condition of the chamber 2 is deficient in fluorine (“fluorine deficient condition” in step S51), the controller 70 is controlled to perform a plasma process with a gas containing fluorine (step S53). The plasma process with the gas containing fluorine is performed to increase the amount of fluorine on the inner surface of the chamber, for example, by adhering fluorine on a thermal-sprayed film, inserting fluorine into the thermal-sprayed film, or fluorinating the thermal-sprayed film. The gas containing fluorine is, for example, a gas containing a CF₄ gas or a NF₃ gas, but is not limited thereto. When the plasma process is completed, the controller 70 ends the post-processing step.

In step S51, when it is estimated in the condition estimating step of step S40 that the condition of the chamber 2 is in excess of fluorine (“fluorine excess condition” in step S51), the controller 70 performs a plasma process with a gas containing oxygen (step S54). The plasma process with the gas containing oxygen is performed to decrease the amount of fluorine on the inner surface of the chamber, for example, by oxidizing the thermal-sprayed film. The gas containing oxygen is, for example, a gas containing an O₂ gas, but is not limited thereto. When the plasma process is completed, the controller 70 ends the post-processing step.

In step S51, when it is estimated in the condition estimating step of step S40 that the condition of the chamber 2 is in a condition in which parts in the chamber 2 are deteriorated (“parts deteriorated condition” in step S51), the controller 70 instructs replacement of the parts (step S55). When the display process is completed, the controller 70 ends the post-processing step.

The method of diagnosing the chamber condition of the present embodiment is carried out, for example, after the start-up of the substrate processing apparatus 1, after the apparatus maintenance of the substrate processing apparatus 1, or before and after the product substrate processing in the substrate processing apparatus 1.

### Apparatus Diagnosis Using Method of Diagnosing Chamber Condition

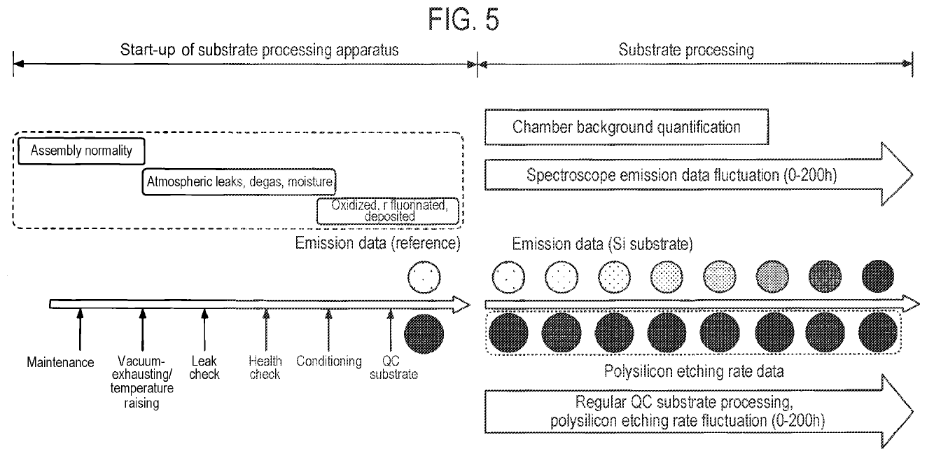

Next, apparatus diagnosis using the method of diagnosing the chamber condition of the present embodiment will be described. FIG. 5 is a conceptual diagram of a time axis of apparatus diagnosis using the method of diagnosing the chamber condition according to the present embodiment.

The left side with respect to the center of FIG. 5 shows a process at the time of starting up the apparatus. The right side with respect to the center of FIG. 5 shows a process of processing the substrate (substrate processing) after the start-up of the apparatus. The elapsed time is shown from left to right.

When starting up the apparatus, the internal temperature of the chamber is raised while vacuum-exhausting after performing maintenance such as assembling the parts or replacing the parts. Then, the chamber is checked for leaks to check the condition of the chamber (health check). Then, a conditioning process is performed. Through the above processes, it is confirmed that the condition of assembly of the parts and the like are normal, the presence or absence of atmospheric leaks is checked, or the presence or absence of degas and moisture is checked. In addition, by performing the conditioning, the inner surface of the chamber is oxidized or fluorinated, or a necessary film and the like is deposited. By starting up the apparatus, the internal state of the chamber is reset to an initial state.

Finally, in order to investigate the quality of the substrate processing apparatus, a QC (quality control) substrate for determining that the condition of the apparatus state is normal is placed on the stage to measure the polysilicon etching rate. In addition, a dummy substrate is placed on the stage to acquire reference emission data. The measurement conditions of the reference emission data are, for example, a chamber pressure of 80 mT, a microwave (2.45 GHz) of 2,000 W, radio frequency power of 100 W, He=300 sccm, and 30 sec. The measurement conditions of the polysilicon etching rate are, for example, a chamber pressure of 120 mT, a microwave (2.45 GHz) of 2,000 W, radio frequency power of 300 W, HBr/O₂/He=800/6/1,000 sccm, and 60 sec.

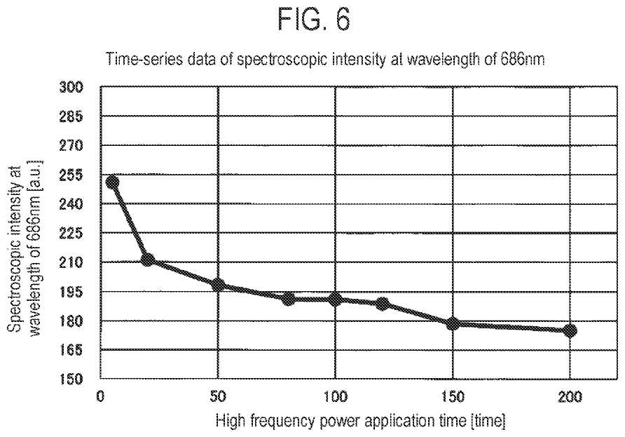

Next, the actual substrate processing is performed. While processing the substrate, the QC substrate is placed on the stage and the polysilicon etching rate is measured at regular time intervals. By measuring the polysilicon etching rate at regular time intervals, fluctuation data of the polysilicon etching rate (polysilicon etching rate fluctuation) are acquired at predetermined intervals, for example, during the processing time of 0 to 200 hours. Immediately before or immediately after the measurement of the polysilicon etching rate, the dummy substrate is placed on the stage to acquire emission data of a predetermined wavelength, that is, the emission wavelength of fluorine in the present embodiment. By acquiring the emission data of fluorine, fluctuation data of the emission data from the spectroscope (spectroscope emission data fluctuation) are acquired at a predetermined interval, for example, during the processing time of 0 to 200 hours. In FIG. 6, as an example, it is schematically shown that the emission data of fluorine becomes smaller with the passage of time. Emission data from the background of the chamber (chamber background) are quantified by acquiring the spectroscope emission data fluctuation).

Once the polysilicon etching rate fluctuation and the spectroscope emission data fluctuation are acquired, the polysilicon etching rate can be estimated from the acquired spectroscope emission data. That is, the measurement of the polysilicon etching rate by the QC substrate can be omitted. That is, the use of the QC substrate can be omitted. Further, since the QC substrate is not used, the costs can be suppressed, and the apparatus diagnosis, for example, the diagnosis of the normal stability of the apparatus can be efficiently performed. By improving the efficiency of the apparatus diagnosis, it is possible to improve the productivity of substrate processing using the apparatus.

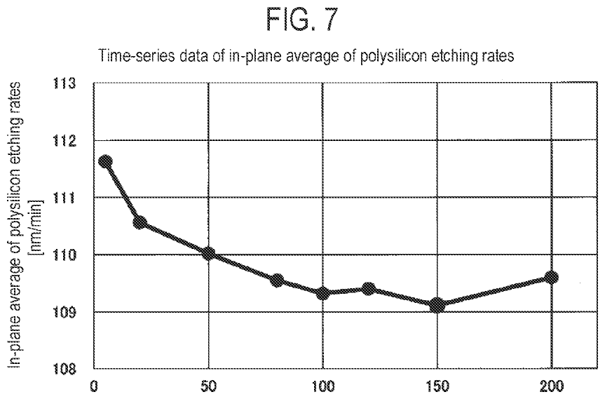

The results of the actual measurement will be described. FIG. 6 is a diagram showing time-series data of emission intensity when using the method of diagnosing the chamber condition according to the present embodiment. FIG. 7 is a diagram showing time-series data of an in-plane average of polysilicon etching rates when using the method of diagnosing the chamber condition according to the present embodiment. The polysilicon etching rate is a rate when the QC substrate is etched using plasma of a gas containing fluorine.

The horizontal axis of FIG. 6 represents the integration time for which radio frequency power is applied to the substrate processing apparatus 1. The vertical axis of FIG. 6 represents the emission intensity at a wavelength of 686 nm. The wavelength of 686 nm is the emission wavelength of fluorine. Therefore, the vertical axis of FIG. 6 represents the emission intensity of fluorine. The emission intensity at the wavelength of 686 nm is the emission intensity (average value for 3 seconds) after 25 seconds from the start of the application of the radio frequency power, that is, after the plasma is generated. The horizontal axis of FIG. 7 represents the integration time for which radio frequency power is applied to the substrate processing apparatus 1. The vertical axis of FIG. 7 represents the in-plane average of polysilicon etching rates.

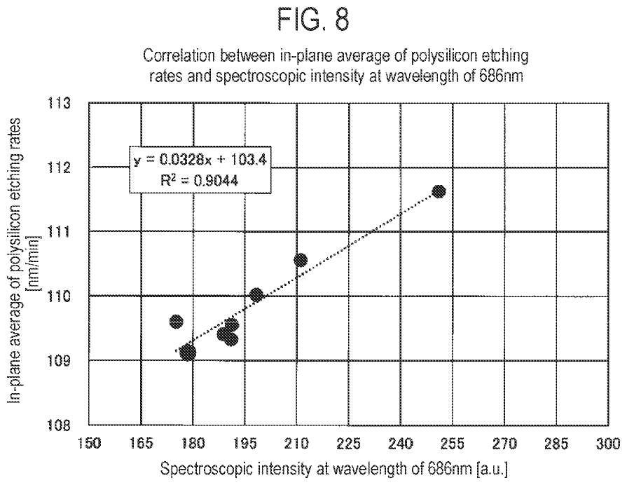

As can be seen from FIGS. 6 and 7, as the application time of radio frequency power becomes longer, the polysilicon etching rate and the emission intensity (spectral intensity) of fluorine decrease. Here, a correlation between the polysilicon etching rate and the emission intensity (spectral intensity) of fluorine will be described. FIG. 8 is a diagram showing the correlation between the in-plane average of polysilicon etching rates and the emission intensity used by the method of diagnosing the chamber condition according to the present embodiment.

It can be seen from the results of FIG. 8 that there is a correlation between the polysilicon etching rate and the emission intensity (spectral intensity) of the emission wavelength of fluorine. That is, by obtaining one of the polysilicon etching rate and the emission intensity (spectral intensity) of the emission wavelength of fluorine, the other can be estimated. For example, the polysilicon etching rate can be estimated by measuring the emission intensity (spectral intensity) of fluorine.

### Plasma Process Using Helium Gas

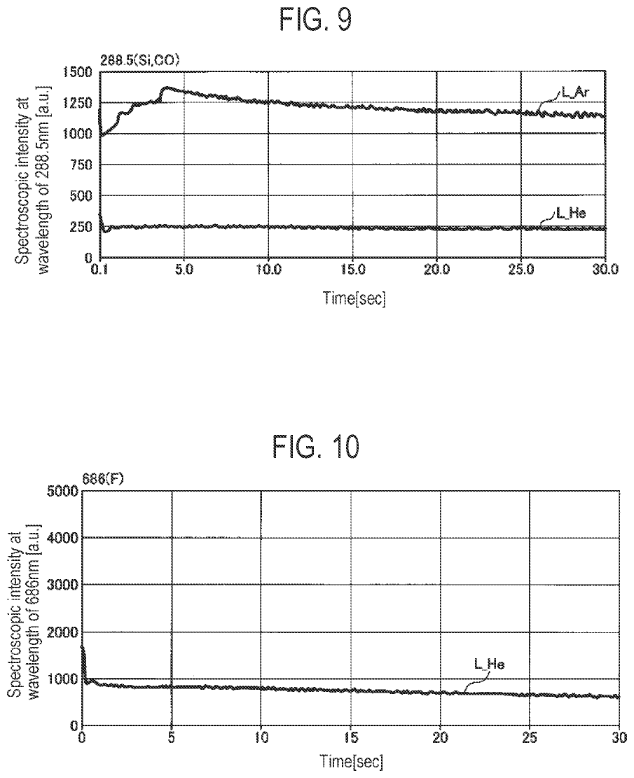

In the present embodiment, a helium gas is used when measuring the emission intensity (spectral intensity) of fluorine. A plasma process using the helium gas will be described. FIG. 9 is a diagram showing a relationship between generated plasma and the emission intensity of a predetermined wavelength. The horizontal axis of FIG. 9 represents the time after radio frequency power is applied, that is, after plasma is generated. The vertical axis of FIG. 9 represents the emission intensity at a wavelength of 288.5 nm. The wavelength of 288.5 nm is the emission wavelength of silicon or carbon monoxide. A line L_He indicates the emission intensity at the wavelength of 288.5 nm in the plasma process using the helium gas. A line L_Ar indicates the emission intensity at the wavelength of 288.5 nm in the plasma process using an argon gas.

Comparing the line L_He and the line L_Ar, the emission intensity in the plasma process using the helium gas converges faster than the emission intensity in the plasma process using the argon gas. For example, the emission intensity in the plasma process using the helium gas stabilizes after about 1 second. On the other hand, the emission intensity in the plasma process using the argon gas takes 10 seconds or more to stabilize. Therefore, in the plasma process using the helium gas, the stable emission intensity can be obtained immediately after the plasma is generated, so that the measurement time (diagnosis time) can be reduced.

FIG. 10 is a diagram showing a relationship between generated plasma and the emission intensity of a predetermined wavelength. The horizontal axis of FIG. 10 represents the time after radio frequency power is applied, that is, after plasma is generated. The vertical axis of FIG. 10 represents the emission intensity at a wavelength of 686 nm. The wavelength of 686 nm is the emission wavelength of fluorine. A line L_He indicates the emission intensity at the wavelength of 686 nm in the plasma process using the helium gas. Even at the emission intensity of the wavelength of 686 nm, the emission intensity in the plasma process using the helium gas stabilizes after about 1 second from the emission of the plasma. In this way, the emission intensity in the plasma process using the helium gas converges quickly. When the plasma process using the argon gas is performed, the argon gas itself peaks at the wavelength of 686 nm. Since the argon gas itself peaks at the wavelength of 686 nm, the emission intensity by fluorine cannot be measured.

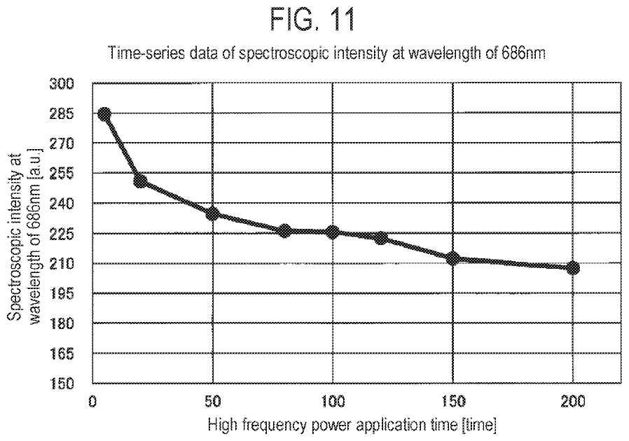

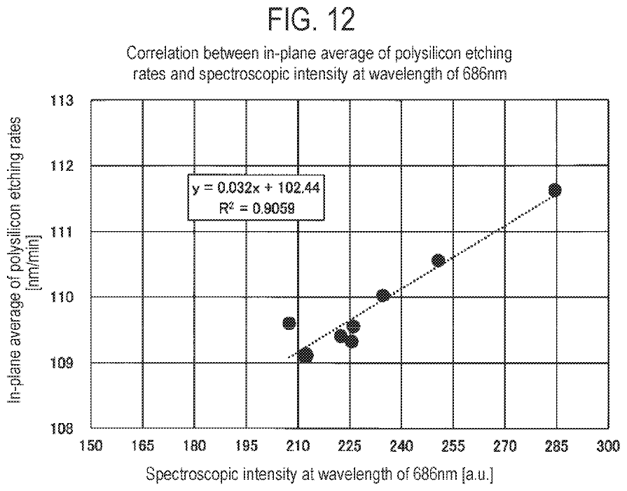

Next, the results of measurements under different condition is shown. FIG. 11 is a diagram showing time-series data of the emission intensity in which the method of diagnosing the chamber condition according to the present embodiment is used. FIG. 12 is a diagram showing a correlation between the in-plane average of polysilicon etching rates and the emission intensity in which the method of diagnosing the chamber condition according to the present embodiment is used.

The horizontal axis of FIG. 11 represents the integration time for which radio frequency power is applied in the substrate processing apparatus 1. The vertical axis of FIG. 11 represents the emission intensity at a wavelength of 686 nm. The wavelength of 686 nm is the emission wavelength of fluorine. Therefore, the vertical axis of FIG. 11 represents the emission intensity of fluorine. The emission intensity at the wavelength of 686 nm is the emission intensity (average value for 3 seconds) after 9 seconds from the start of the application of radio frequency power, that is, from the generation of the plasma.

It can be seen from FIG. 12 that there is a correlation between the polysilicon etching rate and the emission intensity (spectral intensity) of the emission wavelength of fluorine even when the time from the generation of plasma to the measurement of the emission intensity is short. That is, even when the time from the generation of plasma to the measurement of the emission intensity is short, the polysilicon etching rate can be estimated by measuring the emission intensity. Further, the time required for diagnosis can be reduced, thus improving the diagnostic efficiency.

According to the present disclosure in some embodiments, it is possible to provide a technique for diagnosing a chamber condition.

It should be considered that the method of diagnosing the chamber condition in the substrate processing apparatus according to the present embodiments disclosed herein is exemplary in all respects and are not restrictive. The above-described embodiments may be modified or improved in various forms without departing from the scope and spirit of the appended claims. The matters described in the aforementioned embodiments may have other configurations to the extent that they are not inconsistent, and may be combined to the extent that they are not inconsistent.

The method of diagnosing the chamber condition in the substrate processing apparatus of the present disclosure has been described by taking, as an example, an apparatus that generates plasma by a microwave, but the present disclosure is not limited thereto. The present disclosure may be applied to any types of capacitively coupled plasma (CCP), inductively coupled plasma (ICP), electron cyclotron resonance plasma (ECR), helicon wave plasma (HWP), and the like.

What is claimed is:

1. A method of diagnosing a condition of a chamber in a substrate processing apparatus, comprising:
cleaning an interior of the chamber;
generating a plasma from a gas containing a helium gas in the chamber;
measuring an emission intensity of fluorine in the interior of the chamber; and
diagnosing the condition of the chamber based on the emission intensity.

2. The method of claim 1, the gas does not include an argon gas.

3. The method of claim 2, the gas further comprises at least one selected from the group consisting of a xenon gas, a neon gas and a krypton gas.

4. The method of claim 3, wherein the generating the plasma is performed by placing a dummy substrate on a stage.

5. The method of claim 4, wherein the method is performed after a start-up of the substrate processing apparatus, after a maintenance of the substrate processing apparatus, or before and after a processing of a product substrate in the substrate processing apparatus.

6. The method of claim 5, wherein the diagnosing the condition of the chamber further comprises: performing plasma processing with a fluorine-containing gas when the emission intensity is diagnosed to be lower than a first threshold value.

7. The method of claim 6, wherein a surface of the chamber includes a ceramics thermal-sprayed film.

8. The method of claim 7, wherein the ceramics thermal-sprayed film comprises at least one selected from the group consisting of aluminum oxide, yttrium oxide, yttrium fluoride, and yttrium oxyfluoride.

9. The method of claim 1, wherein the generating the plasma is performed by placing a dummy substrate on a stage.

10. The method of claim 1, wherein the method is performed after a start-up of the substrate processing apparatus, after a maintenance of the substrate processing apparatus, or before and after a processing of the product substrate in the substrate processing apparatus.

11. The method of claim 1, wherein the diagnosing the condition of the chamber further comprises: performing plasma processing with a fluorine-containing gas when the emission intensity is diagnosed to be lower than a first threshold value.

12. The method of claim 1, wherein the diagnosing the condition of the chamber further comprises: performing plasma processing with an oxygen-contain gas when the emission intensity is diagnosed to be higher than a second threshold value.

13. The method of claim 1, the gas contains the helium gas only.

14. The method of claim 1, wherein the diagnosing the condition of the chamber further comprises:
performing plasma processing with a fluorine-containing gas when the emission intensity is diagnosed to be less than a first threshold value; and
performing plasma processing with an oxygen-containing gas when the emission intensity is diagnosed to be higher than a second threshold value which is greater than the first threshold value.

15. The method of claim 14, wherein the diagnosing the condition of the chamber further comprises: instructing a part to be replaced when the emission intensity is diagnosed to be less than a third threshold value which is smaller than the first threshold value or when the emission intensity is diagnosed to be greater than a fourth threshold value which is higher than the second threshold value.

16. The method of claim 1, wherein a surface of the chamber includes a ceramics thermal-sprayed film.

17. A substrate processing apparatus, comprising:
a chamber accommodating a substrate therein;
a gas supply source configured to supply a processing gas into the chamber
a plasma source configured to generate a plasma in the chamber;
a measuring member configured to measure an emission intensity of fluorine in the chamber; and
a controller,
wherein the controller controls the chamber, the gas supply source, the plasma source and the measuring member to perform a method of diagnosing a condition of the chamber, the method comprising:
cleaning an interior of the chamber;
generating a plasma from a gas containing a helium gas in the chamber;
measuring the emission intensity of fluorine in the interior of the chamber; and
diagnosing the condition of the chamber based on the emission intensity.

18. The apparatus of claim 17, wherein the plasma source is a microwave plasma source.
